(19) United States
(12) Patent Application Publication
(10) Pub. No.: US 2025/0073843 A1
(43) Pub. Date: Mar. 6, 2025

(54) RETAINER RING MODULE AND CHEMICAL MECHANICAL POLISHING APPARATUS INCLUDING THE SAME

(71) Applicant: SAMSUNG ELECTRONICS CO., LTD., Suwon-si (KR)

(72) Inventors: Imbi Yeo, Suwon-si (KR); Sukhoon Jeong, Suwon-si (KR); Jonghyeon Jeong, Suwon-si (KR); Seyun Park, Suwon-si (KR); Myeongjin Lee, Suwon-si (KR)

(21) Appl. No.: 18/440,747

(22) Filed: Feb. 13, 2024

(30) Foreign Application Priority Data
Aug. 29, 2023 (KR) 10-2023-0113574

(51) Int. Cl. B24B 37/32

(52) U.S. Cl. CPC B24B 37/32

(57) ABSTRACT

An example retainer ring module includes a retainer ring and at least one slurry passage. The retainer ring is arranged on a lower surface of a polishing pad to surround a substrate on an upper surface of the polishing pad to which slurry may be provided. The at least one slurry passage is formed in the retainer ring in a downward slant direction toward a central portion of the retainer ring to introduce the slurry to a space between the substrate and the polishing pad.

### CROSS-REFERENCE TO RELATED APPLICATION

This application claims priority under 35 USC § 119 to Korean Patent Application No. 10-2023-0113574, filed on Aug. 29, 2023, in the Korean Intellectual Property Office (KIPO), the contents of which are herein incorporated by reference in their entirety.

### BACKGROUND

Generally, a layer on a semiconductor substrate may be planarized using a chemical mechanical polishing (CMP) apparatus. The CMP apparatus may include a polishing head, a retainer ring, a platen, a polishing pad, a slurry arm, etc. The polishing pad may hold the semiconductor substrate. The retainer ring may support an edge portion of the semiconductor substrate. The platen may be positioned under the polishing head. The polishing pad may be attached to an upper surface of the platen to polish the semiconductor substrate. The slurry arm may supply slurry to the polishing pad.

According to related arts, the slurry outside the retainer ring may be blocked by the retainer ring so that the slurry may not enter into the retainer ring. That is, the slurry outside the retainer ring may not be introduced into a space between the semiconductor substrate and the polishing pad. This slurry may not be used in a CMP process and may be lost. As a result, a sufficient amount of the slurry may not be provided to the space between the semiconductor substrate and the polishing pad, effectively reducing polishing efficiency.

### SUMMARY

The present disclosure relates to retainer ring modules, including a retainer ring module capable of providing a sufficient amount of slurry to a space between a substrate and a polishing pad to improve polishing efficiency, and a chemical mechanical polishing (CMP) apparatus including the above-mentioned retainer ring.

In general, according to some aspects, a retainer ring module includes a retainer ring and at least one slurry passage. The retainer ring is arranged on a lower surface of a polishing pad to surround a substrate on an upper surface of the polishing pad to which slurry may be provided. The slurry passage is formed in the retainer ring in a downward slant direction toward a central portion of the retainer ring to introduce the slurry to a space between the substrate and the polishing pad.

In general, according to some aspects, a retainer ring module includes a retainer ring, at least one slurry passage and a shutter. The retainer ring is arranged on a lower surface of a polishing pad to surround a substrate on an upper surface of the polishing pad to which slurry may be provided. The slurry passage is formed in the retainer ring in a downward slant direction toward a central portion of the retainer ring to introduce the slurry to a space between the substrate and the polishing pad. The shutter opens and closes the slurry passage. The slurry passage includes an inlet and an outlet. The inlet is formed on an outer side surface of the retainer ring to flow the slurry into the space. The outlet is formed at a lower surface of the retainer ring to discharge the slurry from the space.

In general, according to some aspects, a retainer ring module includes a retainer ring on a lower surface of a polishing head, wherein the retainer ring is configured to surround a substrate on an upper surface of a polishing pad to which slurry is provided; at least one slurry passage formed at the retainer ring in a downward slant direction toward a central portion of the retainer ring, wherein the at least one slurry passage is configured to introduce the slurry outside the retainer ring into a space between the substrate and the polishing pad; and a shutter configured to open and close the at least one slurry passage. The retainer ring comprises a lower surface in contact with the upper surface of the polishing pad; an upper surface in contact with the lower surface of the polishing head; an inner side surface connecting an inner end of the upper surface of the retainer ring and an inner end of the lower surface of the retainer ring; and an outer side surface connecting an outer end of the upper surface of the retainer ring and an outer end of the lower surface of the retainer ring. The at least one slurry passage comprises an inlet formed at an outer side surface of the retainer ring to introduce the slurry; and an outlet formed at a lower surface of the retainer ring to discharge the slurry.

In general, according to some aspects, a CMP apparatus includes a polishing head, a retainer ring module, a platen, a polishing pad and a slurry arm. The polishing head holds a substrate. The retainer ring module is arranged at an edge portion of the polishing head to surround the substrate. The platen is arranged under the polishing head. The polishing pad is arranged on an upper surface of the platen to chemically mechanically polishing the substrate. The slurry arm supplies slurry to the polishing pad. The retainer ring module includes a retainer ring and at least one slurry passage. The retainer ring is arranged on a lower surface of the polishing pad. The slurry passage is formed in the retainer ring in a downward slant direction toward a central portion of the retainer ring to introduce the slurry to a space between the substrate and the polishing pad.

In general, according to some aspects, the slurry outside the retainer ring is introduced into the space between the substrate and the polishing pad through the slurry passage. Thus, a loss of the slurry is decreased. As a result, a sufficient amount of the slurry is provided to the space between the substrate and the polishing pad to improve polishing efficiency.

### BRIEF DESCRIPTION OF THE DRAWINGS

Example implementations will be more clearly understood from the following detailed description taken in conjunction with the accompanying drawings. FIGS. 1 to 19 represent non-limiting, example implementations as described herein.

FIG. 1 is a cross-sectional view illustrating an example of a CMP apparatus.

FIG. 2 is an enlarged cross-sectional view illustrating an example of a polishing head and an example of a retainer ring module of the CMP apparatus in FIG. 1.

FIG. 3 is a perspective view illustrating an example of a retainer ring module in FIG. 2.

FIG. 4 is an example bottom view illustrating the retainer ring module in FIG. 3.

FIG. 5 is an enlarged perspective view illustrating an example of a slurry passage of the retainer ring module in FIG. 3.

FIG. 6 is an example cross-sectional view illustrating the slurry passage in FIG. 5.

FIG. 7 is a cross-sectional view illustrating an example of a retainer ring module.

FIG. 8 is a cross-sectional view illustrating another example of a retainer ring module.

FIG. 9 is a cross-sectional view illustrating another example of a retainer ring module.

FIG. 10 is a cross-sectional view illustrating another example of a retainer ring module.

FIG. 11 is a perspective view illustrating an example of a retainer ring module.

FIG. 12 is an example bottom view illustrating the retainer ring module in FIG. 11.

FIG. 13 is an enlarged perspective view illustrating an example of a slurry passage of the retainer ring module in FIG. 11.

FIG. 14 is a perspective view illustrating another example of a retainer ring module.

FIG. 15 is an example bottom view illustrating the retainer ring module in FIG. 14.

FIG. 16 is an enlarged perspective view illustrating an example of a slurry passage of the retainer ring module in FIG. 14.

FIGS. 17 to 19 are enlarged cross-sectional views illustrating an example of a retainer ring module.

### DETAILED DESCRIPTION

Hereinafter, example implementations will be explained in detail with reference to the accompanying drawings.

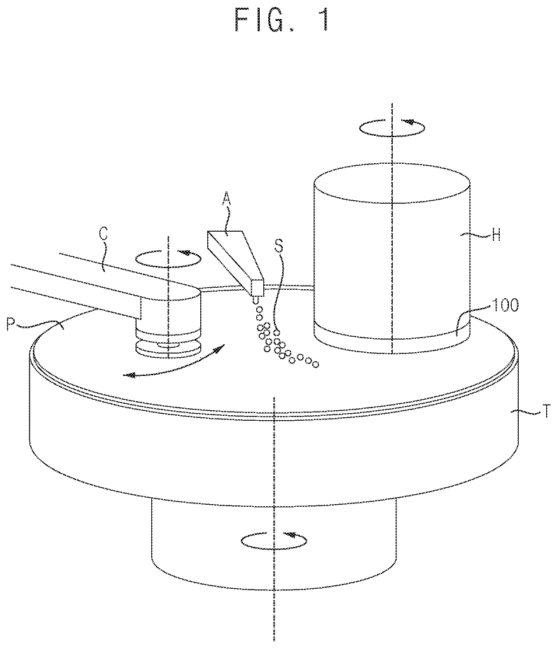

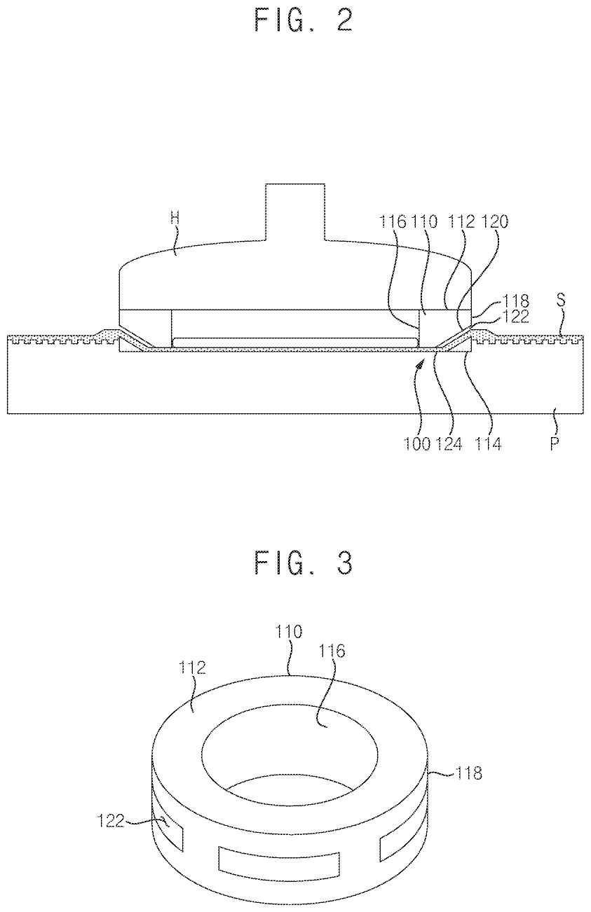

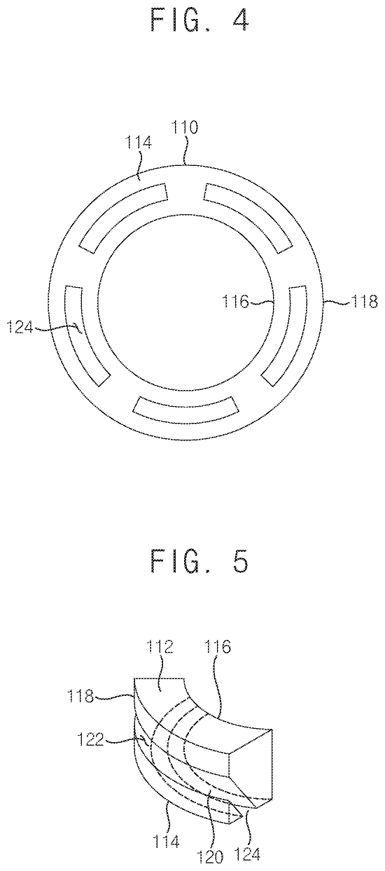

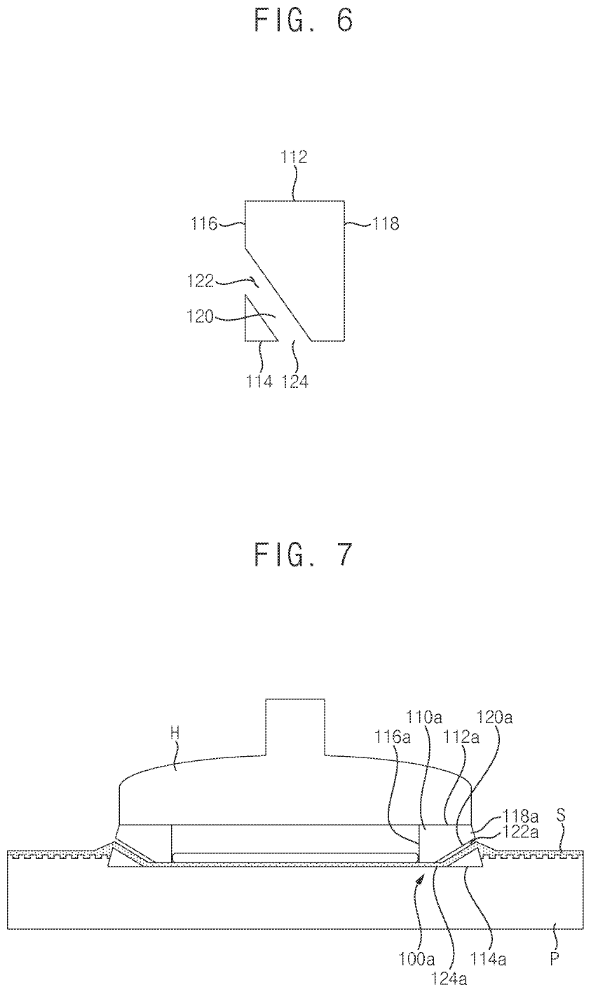

FIG. 1 is a cross-sectional view illustrating an example of a CMP apparatus, FIG. 2 is an enlarged cross-sectional view illustrating an example of a polishing head and an example of a retainer ring module of the CMP apparatus in FIG. 1, FIG. 3 is a perspective view illustrating an example of a retainer ring module in FIG. 2, FIG. 4 is an example bottom view illustrating the retainer ring module in FIG. 3, FIG. 5 is an enlarged perspective view illustrating an example of a slurry passage of the retainer ring module in FIG. 3, and FIG. 6 is an example cross-sectional view illustrating the slurry passage in FIG. 5.

Referring to FIGS. 1 to 6, a CMP apparatus includes a polishing head H, a platen T, a polishing pad P, a slurry arm A and a conditioner C.

The polishing head H may be configured to hold a substrate W. The substrate W may be fixed to a lower surface of the polishing head H. Particularly, the polishing head H may include a membrane and a retainer ring module 100. Vacuum may be provided to the polishing head H to fix the substrate W. The membrane may be arranged on a central portion of the lower surface of the polishing head H. The substrate W may make contact with the membrane.

The retainer ring module 100 may be arranged at an edge portion of the lower surface of the polishing head H to surround the membrane. The retainer ring module 100 may be configured to support an outer circumferential surface of the substrate W in a CMP process. The retainer ring module 100 may be illustrated later in detail.

The platen T may be arranged under the polishing head H. The polishing pad P may be arranged on an upper surface of the platen T. The platen T may be rotated with respect to a vertical axis. Thus, the polishing pad P may also be rotated with respect to the vertical axis together with the platen T. The polishing pad P may chemically mechanically polish a layer on the substrate W, for example, a metal layer using slurry S provided from the slurry arm A. The slurry S may include an oxidizing agent.

The conditioner C may be arranged over the platen T. The conditioner C may include a conditioning disk configured to condition the polishing pad P.

The retainer ring module 100 may include a retainer ring 110 and at least one slurry passage 120. The retainer ring 110 may be arranged at the edge portion of the lower surface of the polishing head H. Thus, the retainer ring 110 may surround the substrate W on the upper surface of the polishing pad P.

In some implementations, the retainer ring 110 may have an upper surface 112, a lower surface 114, an inner side surface 116 and an outer side surface 118. The upper surface 112 of the retainer ring 110 may make contact with the lower surface of the polishing head H. The upper surface 112 of the retainer ring 110 may be a horizontal plane. The lower surface 114 of the retainer ring 110 may make contact with the upper surface of the polishing pad P. The lower surface 114 of the retainer ring 110 may be a horizontal plane. That is, the upper surface 112 and the lower surface 114 of the retainer ring 110 may be substantially parallel to each other. As a result, the upper surface 112 and the lower surface 114 of the retainer ring 110 may have substantially the same width.

The inner side surface 116 of the retainer ring 110 may be connected between an inner end of the upper surface 112 of the retainer ring 110 and an inner end of the lower surface 114 of the retainer ring 110. The inner side surface 116 of the retainer ring 110 may be a vertical plane. Thus, the inner end of the upper surface 112 and the inner end of the lower surface 114 in the retainer ring 110 may have substantially the same radius measured from a center point of the retainer ring 110.

The outer side surface 118 of the retainer ring 110 may be connected between an outer end of the upper surface 112 and an outer end of the lower surface 114 in the retainer ring 110. The outer side surface 118 of the retainer ring 110 may be a vertical plane. Thus, the outer end of the upper surface 112 and the outer end of the lower surface 114 in the retainer ring 110 may have substantially the same radius measured from the center point of the retainer ring 110. That is, the inner side surface 116 and the outer side surface 118 of the retainer ring 110 may be substantially parallel to each other. Further, the inner side surface 116 and the outer side surface 118 of the retainer ring 110 may have substantially the same height.

The slurry passage 120 may be formed in the retainer ring 110 as a slant relative to the polishing pad P. The slurry S positioned outside the retainer ring 110 may be introduced into the retainer ring 110 through the slurry passage 120. Particularly, the slurry S introduced through the slurry passage 120 may be supplied to a space between the substrate W and the polishing pad P.

In some implementations, the slurry passage 120 may be formed in a downward slant direction toward a central portion of the retainer ring 110. Particularly, the slurry passage 120 may include an inlet 122 and an outlet 124. The inlet 122 may be formed at the outer side surface 118 of the retainer ring 110. The slurry S outside the retainer ring 110 may flow into the slurry passage 120 through the inlet 122. The outlet 124 may be formed at the lower surface 114 of the retainer ring 110. The slurry S in the slurry passage 120 may be discharged through the outlet 124. Because the lower surface 114 of the retainer ring 110 may be positioned under the outer side surface 118 of the retainer ring 110, the slurry passage 120 connected between the inlet 122 and the outlet 124 may have a slant shape. Thus, the slurry S outside the retainer ring 110 may readily flow through the slant slurry passage 120. As a result, a sufficient amount of the slurry S may be supplied to the space between the substrate W and the polishing pad P.

In some implementations, the inlet 122 may include a plurality of the inlets 122. The outer 124 may include a plurality of the outlets 124. The inlets 122 may be arranged on the outer side surface 118 of the retainer ring 110 along a circumferential line of the retainer ring 110. The inlets 122 may be spaced apart from each other by a uniform gap, but not limited thereto. The outlets 124 may have an arrangement corresponding to an arrangement of the inlets 122. Thus, the outlets 124 may be arranged on the lower surface 114 of the retainer ring 110 along the circumferential line of the retainer ring 110. The inlet 122 and the outlet 124 may have an arc shape, but not limited thereto. Therefore, the slurry passage 120 may include a plurality of the slurry passages 120 connected between the inlets 122 and the outlets 124, respectively.

FIG. 7 is a cross-sectional view illustrating an example of a retainer ring module.

A retainer ring module 100a of example implementations has a structure substantially the same as the structure of the retainer ring module 100 in FIG. 2 except for a shape of a retainer ring. Thus, any further illustrations with respect to the same structure may be omitted herein for brevity.

Referring to FIG. 7, a retainer ring 110a has an upper surface 112a, a lower surface 114a, an inner side surface 116a and an outer side surface 118a. The upper surface 112a of the retainer ring 110a may be a horizontal plane. The lower surface 114a of the retainer ring 110a may be a horizontal plane. Thus, the upper surface 112a and the lower surface 114a of the retainer ring 110a may be substantially parallel to each other.

The inner side surface 116a of the retainer ring 110a may be a vertical plane. Thus, an inner end of the upper surface 112a and an inner end of the lower surface 114a in the retainer ring 110a may have substantially the same radius measured from a center point of the retainer ring 110a.

In contrast, the outer side surface 118a of the retainer ring 110a may be a slanted surface. Particularly, an outer end of the upper surface 112a of the retainer ring 110a may have a radius shorter than a radius of an outer end of the lower surface 114a of the retainer ring 110a. Thus, a width of the upper surface 112a of the retainer ring 110a may be narrower than a width of the lower surface 114a of the retainer ring 110a.

An inlet 122a of a slurry passage 120a may be formed at the slanted outer side surface 118a of the retainer ring 110a. An outlet 124a of the slurry passage 120a may be formed at the lower surface 114a of the retainer ring 110a.

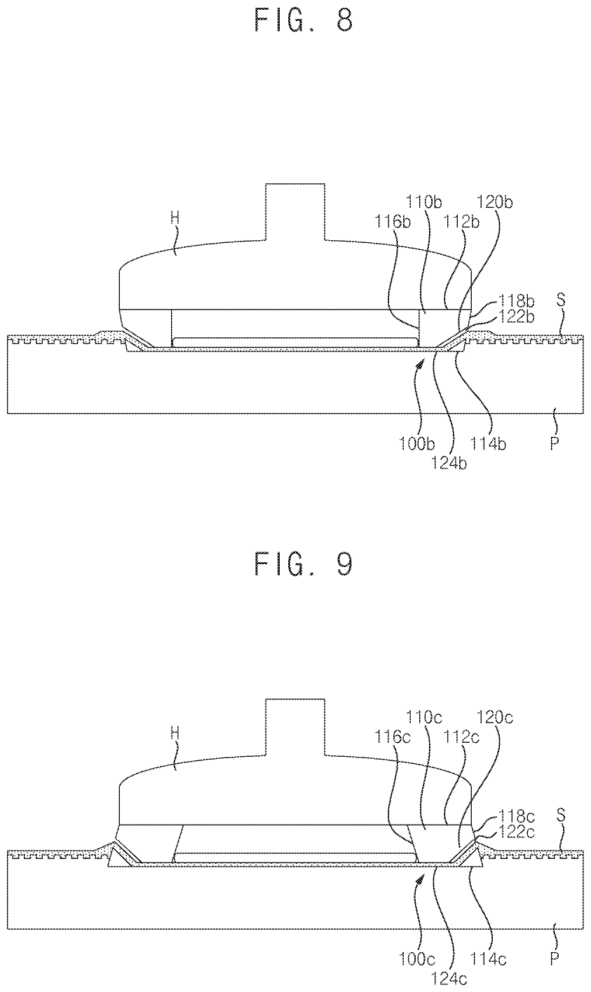

FIG. 8 is a cross-sectional view illustrating another example of a retainer ring module.

A retainer ring module 100b of example implementations has a structure substantially the same as the structure of the retainer ring module 100 in FIG. 2 except for a shape of a retainer ring. Thus, any further illustrations with respect to the same structure may be omitted herein for brevity.

Referring to FIG. 8, a retainer ring 110b has an upper surface 112b, a lower surface 114b, an inner side surface 116b and an outer side surface 118b. The upper surface 112b of the retainer ring 110b may be a horizontal plane. The lower surface 114b of the retainer ring 110b may be a horizontal plane. Thus, the upper surface 112b and the lower surface 114b of the retainer ring 110b may be substantially parallel to each other.

The inner side surface 116b of the retainer ring 110b may be a vertical plane. Thus, an inner end of the upper surface 112b and an inner end of the lower surface 114b in the retainer ring 110b may have substantially the same radius measured from a center point of the retainer ring 110b.

In contrast, the outer side surface 118b of the retainer ring 110b may be a slanted surface. Particularly, an outer end of the upper surface 112b of the retainer ring 110b may have a radius longer than a radius of an outer end of the lower surface 114b of the retainer ring 110b. Thus, a width of the upper surface 112b of the retainer ring 110b may be wider than a width of the lower surface 114b of the retainer ring 110b.

An inlet 122b of a slurry passage 120b may be formed at the slanted outer side surface 118b of the retainer ring 110b. An outlet 124b of the slurry passage 120b may be formed at the lower surface 114b of the retainer ring 110b.

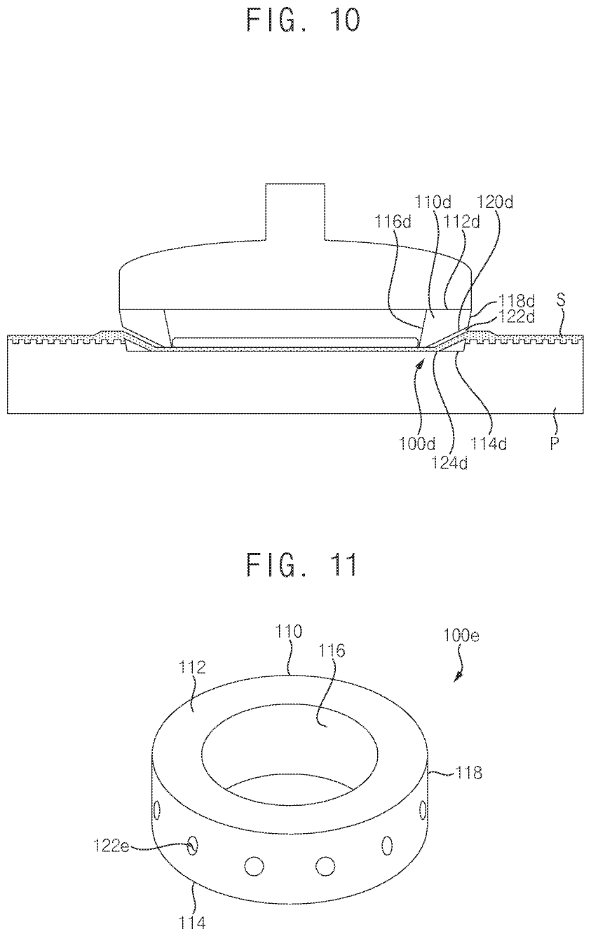

FIG. 9 is a cross-sectional view illustrating another example of a retainer ring module.

A retainer ring module 100c of example implementations has a structure substantially the same as the structure of the retainer ring module 100 in FIG. 2 except for a shape of a retainer ring. Thus, any further illustrations with respect to the same structure may be omitted herein for brevity.

Referring to FIG. 9, a retainer ring 110c has an upper surface 112c, a lower surface 114c, an inner side surface 116c and an outer side surface 118c. The upper surface 112c of the retainer ring 110c may be a horizontal plane. The lower surface 114c of the retainer ring 110c may be a horizontal plane. Thus, the upper surface 112c and the lower surface 114c of the retainer ring 110c may be substantially parallel to each other.

The inner side surface 116c of the retainer ring 110c may be a slanted surface in a right direction. Thus, an inner end of the upper surface 112c of the retainer ring 110c may have a radius shorter than a radius of an inner end of the lower surface 114c of the retainer ring 110c.

The outer side surface 118c of the retainer ring 110c may be a slanted surface in the right direction. Particularly, an outer end of the upper surface 112c of the retainer ring 110c may have a radius shorter than a radius of an outer end of the lower surface 114c of the retainer ring 110c. Further, the inner side surface 116c and the outer side surface 118c of the retainer ring 110c may be substantially parallel to each other. Thus, a width of the upper surface 112c of the retainer ring 110c may be substantially the same as a width of the lower surface 114c of the retainer ring 110c.

An inlet 122c of a slurry passage 120c may be formed at the slanted outer side surface 118c of the retainer ring 110c. An outlet 124c of the slurry passage 120c may be formed at the lower surface 114c of the retainer ring 110c.

FIG. 10 is a cross-sectional view illustrating another example of a retainer ring module.

A retainer ring module 100d of example implementations has a structure substantially the same as the structure of the retainer ring module 100 in FIG. 2 except for a shape of a retainer ring. Thus, any further illustrations with respect to the same structure may be omitted herein for brevity.

Referring to FIG. 10, a retainer ring 110d has an upper surface 112d, a lower surface 114d, an inner side surface 116d and an outer side surface 118d. The upper surface 112d of the retainer ring 110d may be a horizontal plane. The lower surface 114d of the retainer ring 110d may be a horizontal plane. Thus, the upper surface 112d and the lower surface 114d of the retainer ring 110d may be substantially parallel to each other.

The inner side surface 116d of the retainer ring 110d may be a slanted surface in a left direction. Thus, an inner end of the upper surface 112d of the retainer ring 110d may have a radius longer than a radius of an inner end of the lower surface 114d of the retainer ring 110d.

The outer side surface 118d of the retainer ring 110d may be a slanted surface in the left direction. Particularly, an outer end of the upper surface 112d of the retainer ring 110d may have a radius longer than a radius of an outer end of the lower surface 114d of the retainer ring 110d. Further, the inner side surface 116d and the outer side surface 118d of the retainer ring 110d may be substantially parallel to each other. Thus, a width of the upper surface 112d of the retainer ring 110d may be substantially the same as a width of the lower surface 114d of the retainer ring 110d.

An inlet 122d of a slurry passage 120d may be formed at the slanted outer side surface 118d of the retainer ring 110d. An outlet 124d of the slurry passage 120d may be formed at the lower surface 114d of the retainer ring 110d.

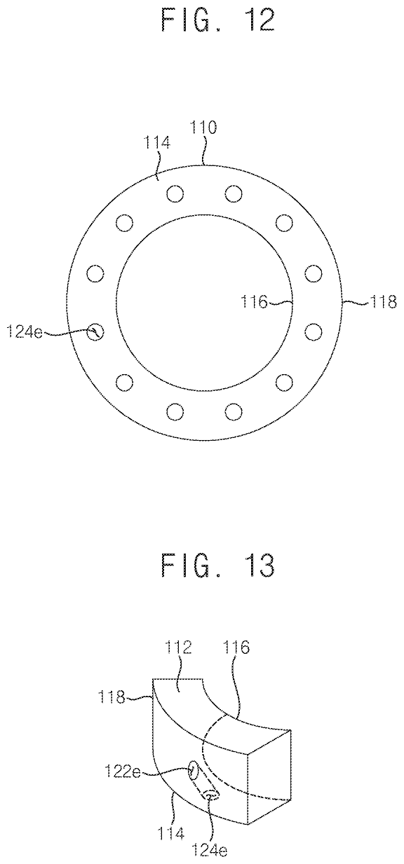

FIG. 11 is a perspective view illustrating an example of a retainer ring module, FIG. 12 is an example bottom view illustrating the retainer ring module in FIG. 11, and FIG. 13 is an enlarged perspective view illustrating an example of a slurry passage of the retainer ring module in FIG. 11.

A retainer ring module 100e of example implementations has a structure substantially the same as the structure of the retainer ring module 100 in FIGS. 3 to 5 except for a slurry passage. Thus, any further illustrations with respect to the same structure may be omitted herein for brevity.

Referring to FIGS. 11 to 13, an inlet 122e and an outlet 124e of a slurry passage 120e have a circular shape. Thus, the slurry passage 120e connected between the inlet 122e and the outlet 124e has a cylindrical shape.

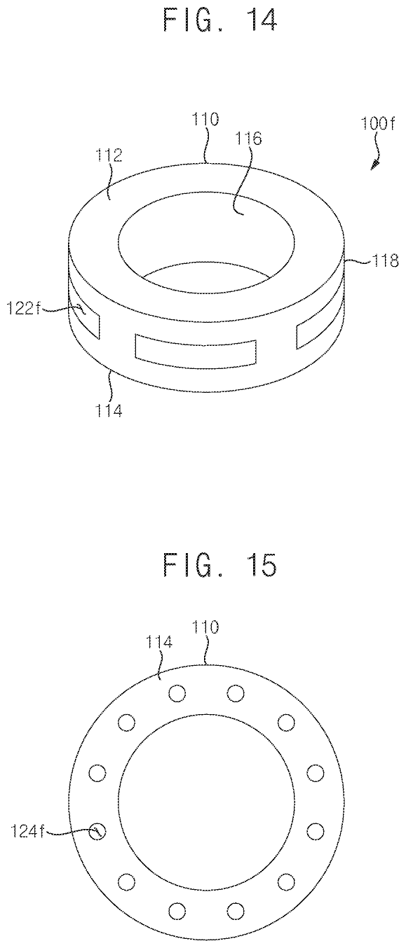

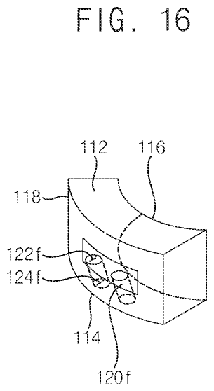

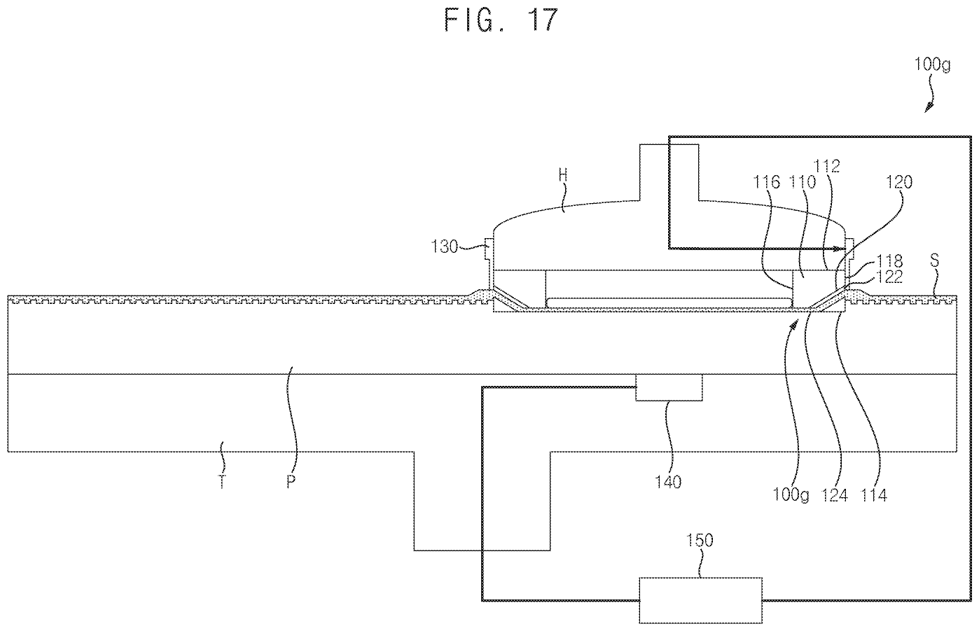

FIG. 14 is a perspective view illustrating another example of a retainer ring module, FIG. 15 is an example bottom view illustrating the retainer ring module in FIG. 14, and FIG. 16 is an enlarged perspective view illustrating another example of a slurry passage of the retainer ring module in FIG. 14.

A retainer ring module 100f of example implementations has a structure substantially the same as the structure of the retainer ring module 100 in FIGS. 3 to 5 except for a slurry passage. Thus, any further illustrations with respect to the same structure may be omitted herein for brevity.

Referring to FIGS. 14 to 16, an inlet 122f has an arc shape. A plurality of outlets 124f are connected with the single inlet 122f through a slurry passage 120f. Each of the outlets 124f has a circular shape, but not limited thereto. The slurry passage 120f has a cylindrical shape, but not limited thereto.

FIGS. 17 to 19 are enlarged cross-sectional views illustrating an example of a retainer ring module.

The retainer ring modules 100g shown in the examples of FIGS. 17-19 have a structure substantially the same as the structure of the retainer ring module 100 in FIG. 2 except for further including a shutter. Thus, any further illustrations with respect to the same structure may be omitted herein for brevity.

Referring to FIG. 17, a shutter 130 may selectively open and close the slurry passage 120. Further, the shutter 130 may control an opening ratio of the slurry passage 120. In some implementations, the shutter 130 may be arranged at the outer side surface 118 of the retainer ring 110, but not limited thereto. The shutter 130 may open and close the inlet 122 of the slurry passage 120.

Particularly, the shutter 130 may control an amount of the slurry S introduced into the slurry passage 120 in accordance with a thickness of the polishing pad P, a lifespan of the polishing pad, etc. In order to control the amount of the slurry S, a thickness sensor 140 may measure the thickness of the polishing pad P. The thickness of the polishing pad P measured by the thickness sensor 140 may be transmitted to a controller 150. The controller 150 may control an operation of the shutter 130 in accordance with the thickness of the polishing pad P.

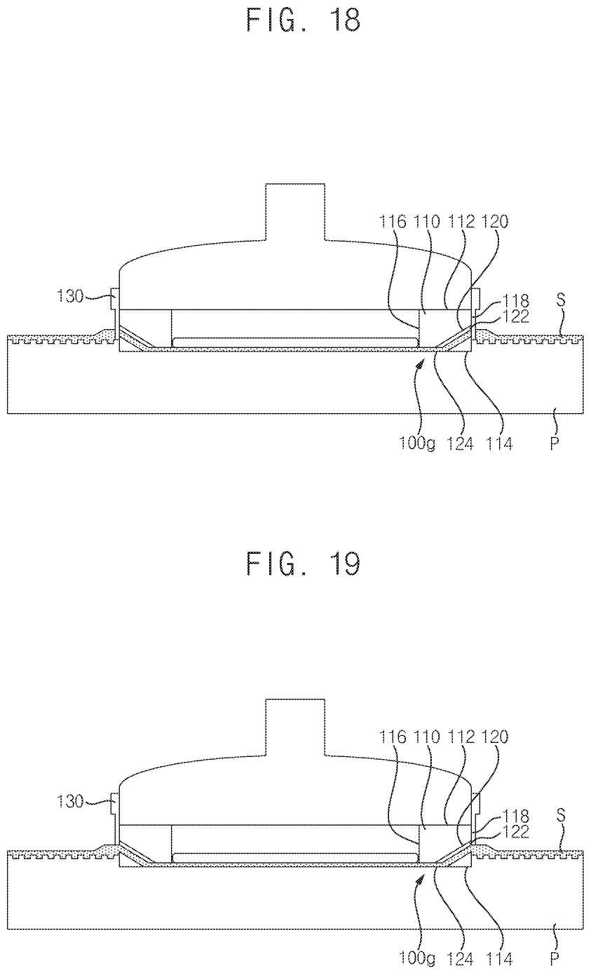

For example, as shown in FIG. 18, the polishing pad P may have a thick thickness in an initial stage of the polishing pad P. In this case, it may not be required to supply a great amount of the slurry S to the polishing pad P. Thus, the shutter 130 may close the inlet 122 of the slurry passage 120. As a result, the slurry S outside the retainer ring 110 may not be introduced into the slurry passage 120.

As shown in FIG. 19, in a middle stage of the polishing pad P, the polishing pad P may be worn to have a thickness of a half of the initial thickness. In this case, the shutter 130 may open a half of the inlet 122 of the slurry passage 120. Thus, a half of the slurry S outside the retainer ring 110 may be supplied to the polishing pad P through the slurry passage 120. As a result, a performance of the half-worn polishing pad P may be maintained.

As shown in FIG. 17, in an end stage of the polishing pad P, the polishing pad P may have a very thin thickness. In this case, the shutter 130 may fully open the inlet 122 of the slurry passage 120. Thus, all the slurry S outside the retainer ring 110 may be supplied to the polishing pad P through the fully opened slurry passage 120. As a result, a sufficient amount of the slurry S may be provided to the polishing pad P so that a performance of the polishing pad P in the end stage may be maintained.

According to some implementations, the slurry outside the retainer ring may be introduced into the space between the substrate and the polishing pad through the slurry passage. Thus, a loss of the slurry may be decreased. As a result, a sufficient amount of the slurry may be provided to the space between the substrate and the polishing pad to improve polishing efficiency.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

The foregoing is illustrative of example implementations and is not to be construed as limiting thereof. Although a few example implementations have been described, those skilled in the art will readily appreciate that many modifications are possible in the example implementations without droplet departing from the novel teachings and advantages of the present disclosure. Accordingly, all such modifications are intended to be included within the scope of the present disclosure as defined in the claims. In the claims, means-plus-function clauses are intended to cover the structures described herein as performing the recited function and not only structural equivalents but also equivalent structures. Therefore, it is to be understood that the foregoing is illustrative of various example implementations and is not to be construed as limited to the specific example implementations disclosed, and that modifications to the disclosed example implementations, as well as other example implementations, are intended to be included within the scope of the appended claims.

What is claimed is:

1. A retainer ring module comprising:
a retainer ring on a lower surface of a polishing head, wherein the retainer ring is configured to surround a substrate on an upper surface of a polishing pad to which slurry is provided; and
at least one slurry passage formed at the retainer ring in a downward slant direction toward a central portion of the retainer ring, wherein the at least one slurry passage is configured to introduce the slurry outside the retainer ring into a space between the substrate and the polishing pad.

2. The retainer ring module of claim 1, wherein the retainer ring comprises:
a lower surface in contact with the upper surface of the polishing pad;
an upper surface in contact with the lower surface of the polishing head;
an inner side surface connecting an inner end of the upper surface of the retainer ring and an inner end of the lower surface of the retainer ring; and
an outer side surface connecting an outer end of the upper surface of the retainer ring and an outer end of the lower surface of the retainer ring.

3. The retainer ring module of claim 2, wherein at least one surface of the inner side surface and the outer side surface is a vertical plane.

4. The retainer ring module of claim 3, wherein the lower surface of the retainer ring has a width larger than a width of the upper surface of the retainer ring.

5. The retainer ring module of claim 3, wherein the lower surface of the retainer ring has a width less than a width of the upper surface of the retainer ring.

6. The retainer ring module of claim 2, wherein the inner side surface is a slanted surface.

7. The retainer ring module of claim 6, wherein the lower surface of the retainer ring has a width substantially the same as a width of the upper surface of the retainer ring.

8. The retainer ring module of claim 7, wherein the inner end of the upper surface of the retainer ring has a radius different from a radius of the inner end of the lower surface of the retainer ring.

9. The retainer ring module of claim 2, wherein the at least one slurry passage comprises:
an inlet formed at the outer side surface of the retainer ring, wherein the inlet is configured to introduce the slurry; and
an outlet formed at the lower surface of the retainer ring, wherein the outlet is configured to discharge the slurry.

10. The retainer ring module of claim 9, wherein a plurality of inlets are arranged in a circumferential line of the retainer ring, and a plurality of outlets are arranged in the circumferential line of the retainer ring corresponding to the plurality of inlets.

11. The retainer ring module of claim 10, wherein each inlet of the plurality of inlets and each outlet the plurality of outlets have an arc shape or a circular shape.

12. The retainer ring module of claim 10, wherein each inlet of the plurality of inlets has an arc shape and each outlet of the plurality of outlets has a circular shape.

13. The retainer ring module of claim 1, comprising a shutter configured to open and close the at least one slurry passage.

14. The retainer ring module of claim 13, wherein the shutter is at an outer side surface of the retainer ring.

15. A retainer ring module comprising:
a retainer ring on a lower surface of a polishing head, wherein the retainer ring is configured to surround a substrate on an upper surface of a polishing pad to which slurry is provided;
at least one slurry passage formed at the retainer ring in a downward slant direction toward a central portion of the retainer ring, wherein the at least one slurry passage is configured to introduce the slurry outside the retainer ring into a space between the substrate and the polishing pad; and
a shutter configured to open and close the at least one slurry passage,
wherein the at least one slurry passage comprises:
an inlet formed at an outer side surface of the retainer ring to introduce the slurry; and
an outlet formed at a lower surface of the retainer ring to discharge the slurry.

16. The retainer ring module of claim 15, wherein the retainer ring comprises:
a lower surface in contact with the upper surface of the polishing pad;
an upper surface in contact with the lower surface of the polishing head;
an inner side surface connecting an inner end of the upper surface of the retainer ring and an inner end of the lower surface of the retainer ring; and
an outer side surface connecting an outer end of the upper surface of the retainer ring and an outer end of the lower surface of the retainer ring.

17. The retainer ring module of claim 16, wherein at least one surface of the inner side surface and the outer side surface is a vertical plane, and the lower surface of the retainer ring has a width larger than a width of the upper surface of the retainer ring.

18. The retainer ring module of claim 16, wherein the inner side surface is a slanted surface, and the lower surface of the retainer ring has a width substantially the same as a width of the upper surface of the retainer ring.

19. A retainer ring module comprising:
a retainer ring on a lower surface of a polishing head, wherein the retainer ring is configured to surround a substrate on an upper surface of a polishing pad to which slurry is provided;
at least one slurry passage formed at the retainer ring in a downward slant direction toward a central portion of the retainer ring, wherein the at least one slurry passage is configured to introduce the slurry outside the retainer ring into a space between the substrate and the polishing pad; and
a shutter configured to open and close the at least one slurry passage,
wherein the retainer ring comprises:
a lower surface in contact with the upper surface of the polishing pad;
an upper surface in contact with the lower surface of the polishing head;
an inner side surface connecting an inner end of the upper surface of the retainer ring and an inner end of the lower surface of the retainer ring; and
an outer side surface connecting an outer end of the upper surface of the retainer ring and an outer end of the lower surface of the retainer ring, and
wherein the at least one slurry passage comprises:
an inlet formed at an outer side surface of the retainer ring to introduce the slurry; and
an outlet formed at a lower surface of the retainer ring to discharge the slurry.

20. The retainer ring module of claim 19, wherein at least one surface of the inner side surface and the outer side surface is a vertical plane.
